(19) United States
(12) Patent Application Publication
(10) Pub. No.: US 2025/0338642 A1
(43) Pub. Date: Oct. 30, 2025

(54) INSULATING TRENCH AND METHOD OF MAKING SAME

(71) Applicant: STMicroelectronics International N.V., Geneva (CH)

(72) Inventor: Boris RODRIGUES GONCALVES, THEYS (FR)

(73) Assignee: STMicroelectronics International N.V., Geneva (CH)

(21) Appl. No.: 19/187,358

(22) Filed: Apr. 23, 2025

(30) Foreign Application Priority Data
Apr. 30, 2024 (FR) FR2404502

(51) Int. Cl. H10F 39/00

(52) U.S. Cl. CPC H10F 39/014; H10F 39/807

(57) ABSTRACT

A trench within a semiconductor substrate includes a liner made of a P-type doped semiconductor layer formed by epitaxial growth on the side walls and bottom of the trench. An insulating material partially or fully fills the trench.

### PRIORITY CLAIM

This application claims the priority benefit of French Application for Patent No. FR 2404502 filed on Apr. 30, 2024, the content of which is hereby incorporated by reference in its entirety to the maximum extent allowable by law.

### TECHNICAL FIELD

The present disclosure generally concerns electronic systems and circuits, and further concerns manufacturing methods for electronic systems and circuits. The present disclosure more particularly concerns the insulation of electronic components, and the use of insulating trenches for this purpose.

### BACKGROUND

The correct operation of electronic devices comprising one or a plurality of electronic components may generally require the electrical insulation of this or these component(s) from other components and/or from the external environment.

The use of insulating trenches is a well-known electrical insulation means.

It would be desirable to be able to improve, at least partly, certain aspects of electronic devices and of their manufacturing methods.

There exists a need for electronic devices comprising electrically-insulated electronic components, and which exhibit current leakage.

There exists a need for electronic devices comprising electrically-insulated pixels, and which exhibit current leakage.

There exists a need for electronic devices comprising electronic components laterally electrically insulated by using insulating trenches enabling to limit current leakage.

There is a need to overcomes all or part of the disadvantages of known electronic devices comprising electrically-insulated electronic components enabling to limit current leakage.

### SUMMARY

An embodiment provides electrically insulating an electronic component by using at least one insulating trench.

An embodiment provides electrically insulating an electronic component by using at least one insulating trench having its walls covered with a heavily doped P-type semiconductor layer.

An embodiment provides forming this semiconductor layer by epitaxial growth.

An embodiment provides an insulating trench formed from a first surface of a semiconductor substrate comprising on all its side walls a P-type doped semiconductor layer formed by epitaxial growth.

According to an embodiment, the trench has a depth greater than 3 μm.

According to an embodiment, said semiconductor layer has a concentration of P-type dopant elements greater than 1×10¹⁷ atoms·cm⁻³.

According to an embodiment, said semiconductor layer has a thickness greater than 5 nm.

According to an embodiment, the trench comprises a core made of an electrically-insulating material.

According to an embodiment, said core comprises silicon oxide.

Another embodiment provides an electronic device comprising an electronic component being electrically and laterally insulated by at least one above-described insulating trench.

According to an embodiment, said component is a pixel.

Another embodiment provides a method of manufacturing an insulating trench, comprising the following successive steps: a) etching a first cavity from a first surface of a semiconductor substrate; b) epitaxially growing a P-type doped semiconductor material on the walls of said first cavity; and c) filling said first cavity with an electrically-insulating material.

According to an embodiment, the method comprises, between steps b) and c), the following successive steps: d) grinding said semiconductor substrate from a second surface opposite to the first surface until reaching the bottom of said first cavity; and e) forming a second cavity from said second surface of said semiconductor substrate, said second cavity having a width smaller than a width of said first cavity.

Another embodiment provides a method of manufacturing a previously-described device comprising the previously-described insulating trench manufacturing method.

According to an embodiment, said component is formed from said first surface of said semiconductor substrate.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 shows a cross-section view of an electronic device;

FIG. 2 shows two graphs (A) and (B) illustrating the advantage of the embodiment of FIG. 1;

FIGS. 3 to 6 show cross-section view of a sequence of steps of a method of manufacturing the embodiment of FIG. 1; and

FIGS. 7 to 14 show cross-section view of a sequence of steps of a method of manufacturing the embodiment of FIG. 1.

### DETAILED DESCRIPTION

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10%, preferably of plus or minus 5%.

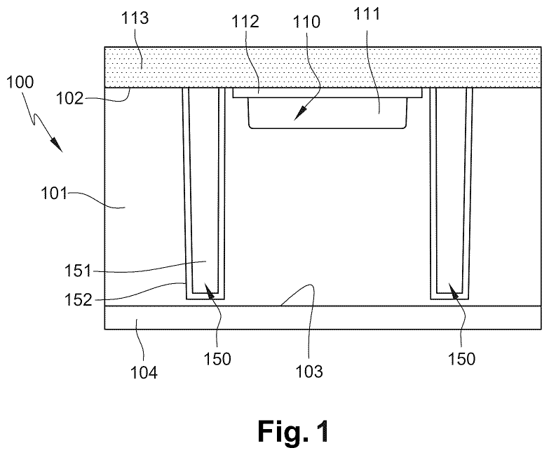

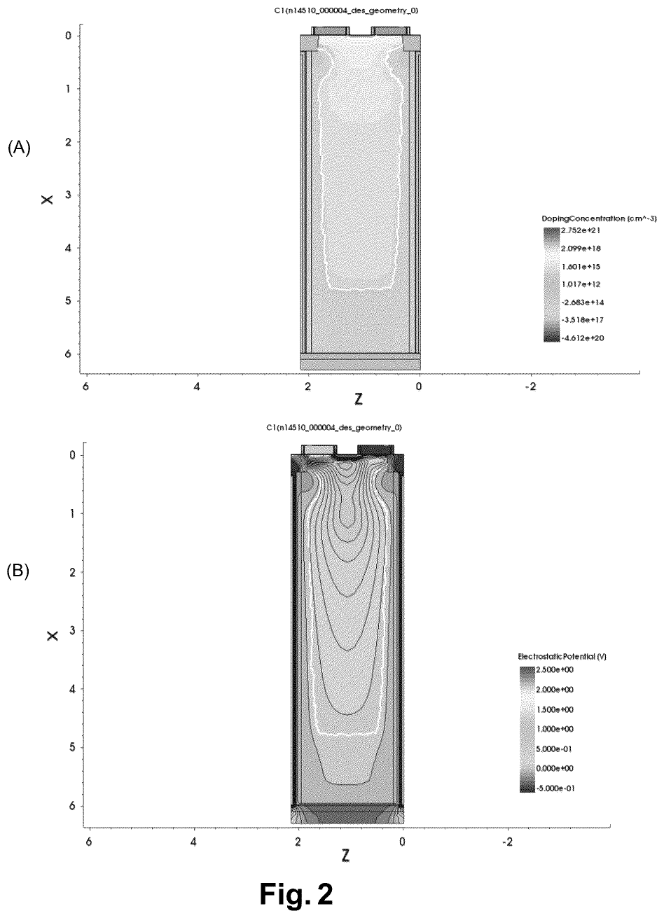

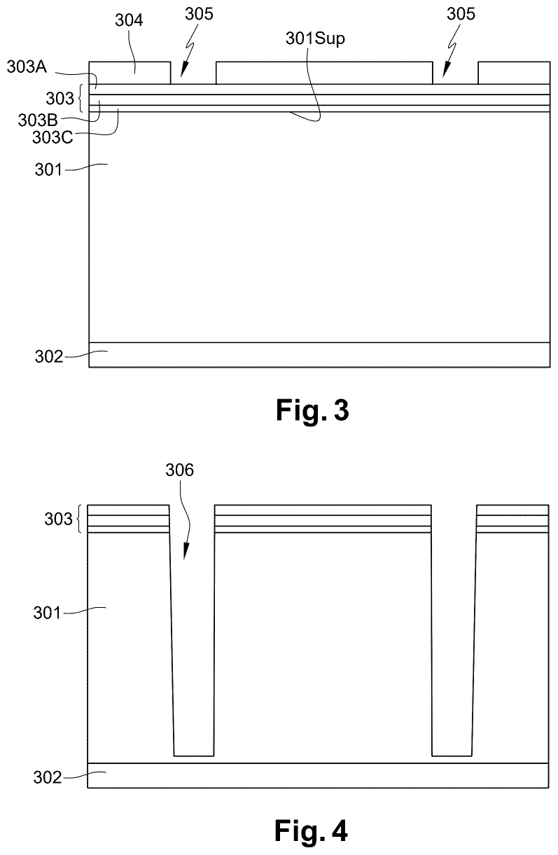

The embodiments described hereafter concern the insulation of electronic components formed inside and on top of a semiconductor substrate. The use of insulating trenches is common to electrically and laterally insulate electronic components. It is known that an electronic component can exhibit leakage currents even while being surrounded by insulating trenches. The inventors have discovered that introducing a heavily-doped P-type layer at the wall of insulating trenches enables to limit these leakage currents. Such an insulating trench is described in relation with FIGS. 1 and 2. Two methods of manufacturing such an insulating trench are described in relation with FIGS. 3 to 6 and 7 to 14.

In addition, the embodiments described hereafter are particularly adapted to the insulation of electronic components of imager component type, such as pixels.

Further, the above-described embodiments are particularly adapted to being used in any type of industry where an electrical insulation of electronic components is required. More particularly, such an insulating trench may be intended for: the automotive industry, for example in the field of automotive electrification or in the field of advanced driver assistance systems (ADAS); the industrial field, for example in the field of green energy, in the field of infrastructure electrification, of the Internet of Things (IoT) and of smart homes, where electricity and energy consumption and data exchange are key elements; the personal electronics industry, for example in the field of mobile telephony and of the Internet of Things (IoT), as well as in the field of broadband interfaces; and the industry of communications equipment, computers, and peripherals, for example in infrastructure and data centers, and in the field of low earth orbit (LEO) satellites.

FIG. 1 is a cross-section view of an embodiment of an electronic device 100 comprising an embodiment of an insulating trench 150.

Device 100 is formed from a semiconductor substrate 101 comprising an upper surface 102 and a lower surface 103, opposite to upper surface 102. According to an example, substrate 101 is made of a semiconductor material, that is, of a material comprising at least one chemical element from column IV of the periodic table of elements, such as silicon (Si) or germanium (Ge). According to an embodiment, substrate 101 is made of silicon. According to an example, substrate 101 may rest on a support 104, such as another substrate for example. In this case, the lower surface 103 of the substrate is in contact with support 104.

Device 100 comprises an electronic component 110 which is laterally insulated by one or a plurality of insulating trenches 150.

According to an example, electronic component 110 is formed inside and/or on top of substrate 101 from its upper surface 102. Electronic component 110 may be a single electronic component or a circuit comprising a plurality of electronic components. According to a preferred embodiment illustrated in FIG. 1, component 110 is a pixel that can be used in an imaging circuit, such as a display. According to the preferred embodiment, component 110 comprises a photodiode 111 formed in substrate 101 and a layer 112 extending between the upper surface 102 of substrate 101 and photodiode 111. According to an example, layer 112 is a heavily doped P-type surface layer, formed by implantation to manufacture a pinned diode.

According to an example, component 110 may comprise metallization levels 113 resting on the upper layer 102 of substrate 101.

According to an embodiment, insulating trench(es) 150 extend(s) from the upper surface 102 of substrate 101. In FIG. 1, two trenches 150 are shown. Insulating trench(es) 150 are formed by an insulating core 151 and a semiconductor layer 152, also known as liner 152. The insulating core forms the inner portion of insulating trench 150, and is made of an insulating material, such as for example silicon oxide. According to an embodiment, semiconductor layer 152 is P-doped, preferably heavily P-doped, and covers the side walls and the bottom of insulating trench 150. According to an embodiment, layer 152 is obtained by epitaxial growth, which enables to obtain a uniform doping of layer 152, and a clean interface between core 151 and layer 152. Implementation modes of methods of manufacturing a device of the type of device 100 are described in relation with FIGS. 3 to 6 and FIGS. 7 to 14.

According to an example, trench or trenches 150 have a depth greater than 3 μm, preferably greater than 6 μm. Trench or trenches 150 have a width in the range from 100 to 500 nm, for example in the order of 200 nm.

According to an embodiment, the concentration of P-type dopant elements of layer 150 is greater than 1×10¹⁷ atoms·cm⁻³. According to an example, the doping elements used to dope layer 150 comprise one or a plurality of elements from column III of the periodic table of elements, such as boron. According to an example, layer 150 has a thickness greater than 5 nm, for example in the order of 10 nm.

An advantage of using a layer of the type of layer 151 is described in relation with FIG. 2.

FIG. 2 comprises two graphs (A) and (B).

Graph (A) of FIG. 2 illustrates, in grey levels, the concentration of dopant elements in a region between two insulating trenches of the type of the trench 150 described in relation with FIG. 1.

Graph (B) of FIG. 2 illustrates, by lines and grey levels, the electrostatic potential and associated current lines in a region between two insulating trenches of the type of the trenches 150 described in relation with FIG. 1.

Graphs (A) and (B) show that using a heavily doped P-type liner enables to prevent a parasitic electrical conduction along the insulating trenches, which causes leakage currents. Indeed, graph (A) shows that the implantation of dopant elements in this region is prevented at the junction between said region and the insulating trenches. Graph (B) shows that current lines remain confined in this region.

FIGS. 3 to 6 illustrate steps of a first implementation mode of a method of manufacturing a device of the type of the device 100 described in relation with FIG. 1.

The manufacturing method of FIGS. 3 to 6 concerns a method of manufacturing an insulating trench of the type of insulating trenches 150 described in relation with FIG. 1. More particularly, this method is a method of front-side manufacturing of a semiconductor substrate.

At the initial step of FIG. 3, there is considered a semiconductor substrate 301, resting on a support 302 of the type of the substrate 101 and support 104 described in relation with FIG. 1. A mask enabling to prepare a subsequent etching operation is installed on an upper surface 301Sup of substrate 301.

This mask is formed of a protective stack 303, and of a mask layer 304 comprising openings 305. Stack 303 comprises: an insulating layer 303A, for example made of silicon oxide, resting on surface 301Sup of substrate 301; a layer 303B, for example made of nitrate, resting on layer 303A; and an insulating layer 303C, for example made of silicon oxide, resting on layer 303B.

Mask layer 304 is, for example, a resin layer remaining after the photolithography process. Openings 305 designate the future location of the insulating trenches.

At the step of FIG. 4, an operation of etching of cavity 306 is executed. Cavities 306 have the dimensions of the desired insulating trenches. According to an example, cavities 306 have a depth greater than 3 μm, preferably greater than 6 μm. Cavities 306 have a width in the range from 100 to 500 nm, for example in the order of 200 nm.

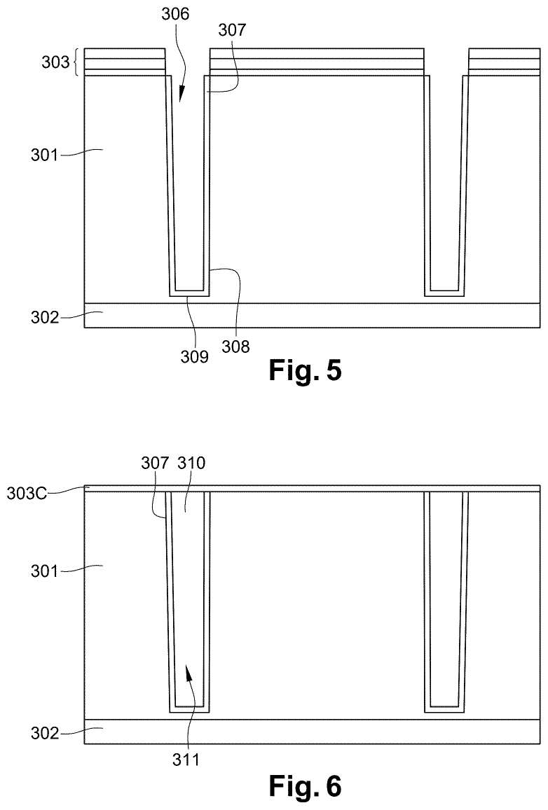

At the step of FIG. 5, a heavily-doped P-type semiconductor layer 307 of the type of the liner 152 described in relation with FIG. 1 is formed. According to an example, layer 307 is formed by epitaxial growth and covers the side walls and the bottom of cavities 306.

At the step of FIG. 6, cavity 306 is filled with an insulating material 310 to form an insulating trench 311. Insulating material 310 forms the core of the insulating trench. According to an example, material 310 is silicon oxide. Insulating trench 311 is thus of the same type as the trench 150 described in relation with FIG. 1.

The step of FIG. 6 can then be followed by steps of manufacturing of an electronic component between trenches 311. According to a variant, these steps may be executed prior to the steps described in relation with FIGS. 3 to 6.

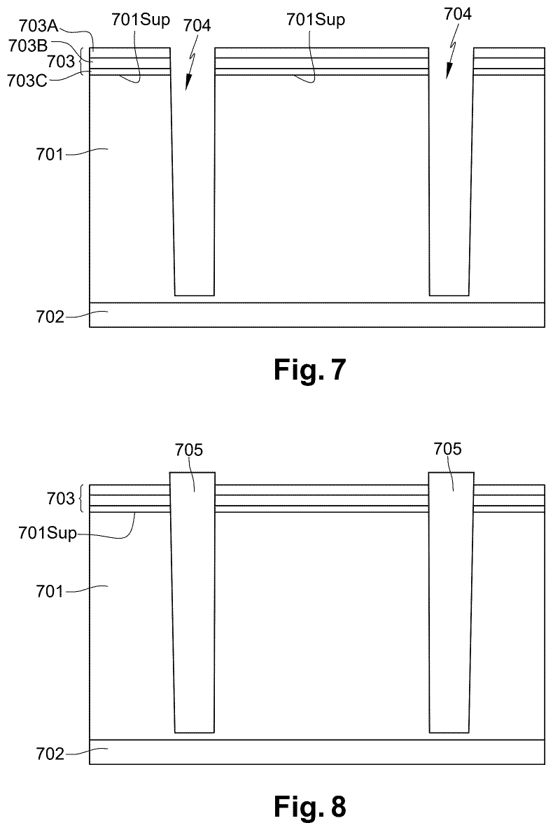

FIGS. 7 to 14 illustrate steps of a second implementation mode of a method of manufacturing a device of the type of the device 100 described in relation with FIG. 1.

The manufacturing method of FIGS. 7 to 14 concerns a method of manufacturing an insulating trench of the type of the insulating trenches 150 described in relation with FIG. 1. More particularly, this method is a method of backside manufacturing of a semiconductor substrate.

At the initial step of FIG. 7, similar to the step of FIG. 4, there is considered a semiconductor substrate 701, resting on a support 702 of the type of the substrate 101 and support 104 described in relation with FIG. 1. A protective stack 703 is formed on an upper surface 701Sup of substrate 701. Stack 703 comprises: an insulating layer 703A, for example made of silicon oxide, resting on surface 701Sup of substrate 701; a layer 703B, for example made of nitrate, resting on layer 703A; and an insulating layer 703C, for example made of silicon oxide, resting on layer 703B.

Cavities 704 are etched in substrate 701 in the same way as described in relation with FIGS. 3 and 4. Cavities 704 have the dimensions of the desired insulating trenches. According to an example, cavities 704 have a depth greater than 3 μm, preferably greater than 6 μm. Cavities 704 have a width in the range from 100 to 500 nm, for example in the order of 200 nm.

At the step of FIG. 8, a heavily-doped P-type semiconductor material 705 is formed in the cavities. According to an example, the material is formed by epitaxial growth and completely fills cavities 705.

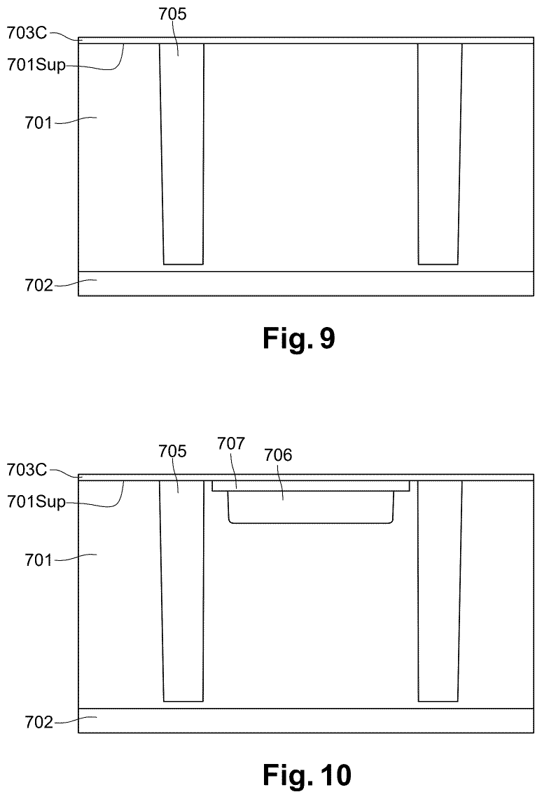

At the step of FIG. 9, an etching operation is implemented to flatten the upper surface of the structure obtained at the end of the step of FIG. 8. During this step, excess material 705 protruding from surface 701Sup of substrate 701, and layers 703A and 703B are removed.

At the step of FIG. 10, steps of manufacturing of an electronic component arranged between the insulating trenches may be implemented. In the example illustrated in FIG. 10, a pixel-type component, similar to the component 110 described in relation with FIG. 1, comprises a photodiode 706 and an optical insulation layer 707. According to an example, photodiode 706 is formed in substrate 701. According to an example, the optical insulation layer is placed between photodiode 706 and the upper surface 701Sup of substrate 701.

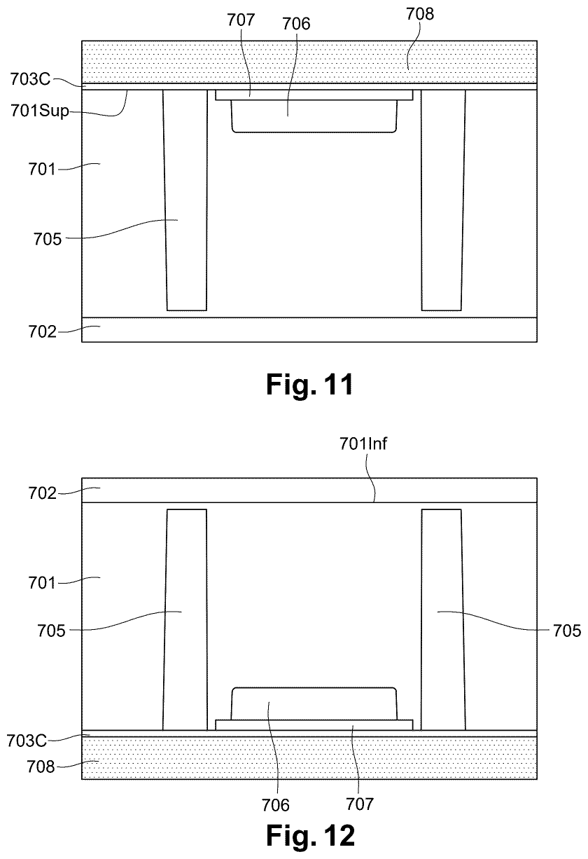

At the step of FIG. 11, possible metallization levels 708 are formed on the remaining layer 703C of the stack. According to an example, metallization levels 708 are connected to the component formed at step 10.

At the step of FIG. 12, the structure obtained at the step of FIG. 11 is turned upside down to gain access to the rear surface 701Inf, or lower surface 701Inf, of substrate 701. Lower surface 701Inf is opposite to upper surface 701Sup.

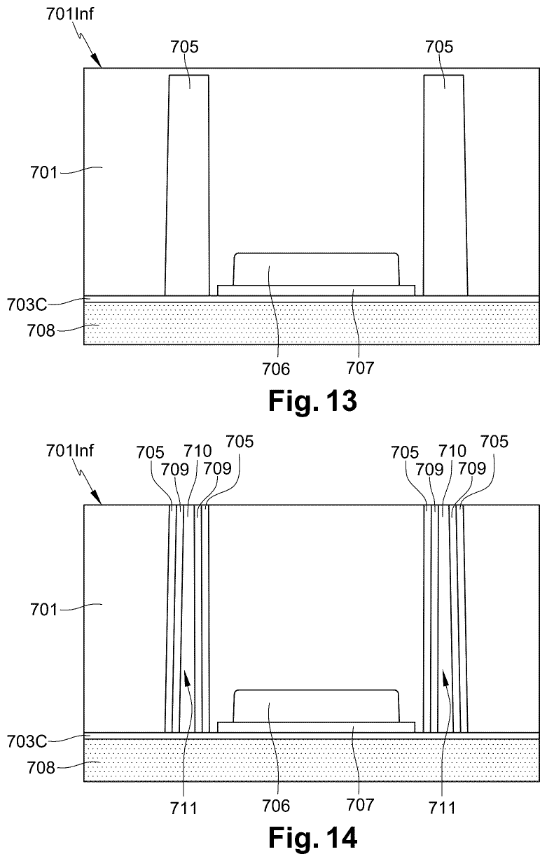

At the step of FIG. 13, support 702 is removed and an operation of grinding of the rear surface 701Inf of substrate 701 is implemented. The grinding is stopped when the bottom of cavities 704 is reached, that is, when material 705 is exposed.

At the step of FIG. 14, an operation of etching of material 705 is implemented to form a cavity 710 in material 705. This step aims at forming the core of the insulating trench. The etch step enables to thin material 705 until it forms only a layer covering the side walls of the initial cavity 704. In other words, the etch step enables to form a cavity 710 having a width smaller than a width of said cavity 704. Thus, material 705 is transformed into a layer of the type of the layer 152 described in relation with FIG. 1.

Once cavity 710 has been formed, it is partially (as shown in FIG. 14) or completely filled with an electrically-insulating material 709, for example silicon oxide. An insulating trench 711 of the type of the trench 150 described in relation with FIG. 1 is thus formed.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

1. A method of manufacturing an insulating trench, comprising the following successive steps:
a) etching a first cavity from a first surface of a semiconductor substrate;
b) epitaxially growing a P-type doped semiconductor material on walls of said first cavity; and
c) filling said first cavity with an electrically-insulating material.

2. The method according to claim 1, wherein said first cavity has a depth greater than 3 μm.

3. The trench according to claim 1, wherein said semiconductor layer has a concentration of P-type dopant elements greater than 1×10¹⁷ atoms·cm⁻³.

4. The method according to claim 1, wherein said semiconductor layer is greater than 5 nm thick.

5. The method according to claim 1, further comprising forming an electronic component at the first surface of the semiconductor substrate, wherein the electronic component is electrically and laterally insulated by the first cavity filled with the electrically-insulating material.

6. The method according to claim 5, wherein said electronic component is a pixel.

7. The method according to claim 1, wherein said insulating material comprises silicon oxide.

8. An integrated circuit device made using the method of claim 1.

9. A method of manufacturing an insulating trench, comprising the following successive steps:
a) etching a first cavity from a first surface of a semiconductor substrate;
b) epitaxially growing a P-type doped semiconductor material on walls of said first cavity to fill the first cavity with the P-type doped semiconductor material;
c) grinding said semiconductor substrate from a second surface opposite to the first surface until reaching a bottom of said first cavity;
d) forming a second cavity from said second surface of said semiconductor substrate in said P-type doped semiconductor material, said second cavity having a width smaller than a width of said first cavity; and
e) filling said second cavity with an electrically-insulating material.

10. The method according to claim 9, wherein said first cavity has a depth greater than 3 μm.

11. The trench according to claim 9, wherein said semiconductor layer has a concentration of P-type dopant elements greater than 1×10¹⁷ atoms·cm⁻³.

12. The method according to claim 9, wherein said semiconductor layer is greater than 5 nm thick.

13. The method according to claim 9, further comprising forming an electronic component at the first surface of the semiconductor substrate, wherein the electronic component is electrically and laterally insulated by the first cavity filled with the electrically-insulating material.

14. The method according to claim 13, wherein said electronic component is a pixel.

15. The method according to claim 9, wherein said insulating material comprises silicon oxide.

16. An integrated circuit device made using the method of claim 9.
